(19) United States
(12) Patent Application Publication
(10) Pub. No.: US 2019/0355110 A1
(43) Pub. Date: Nov. 21, 2019

(54) CROSS TALK REDUCTION

(71) Applicant: CAMTEK LTD.

(72) Inventor: DROR COHEN, MIGDAL HAEMEQ (IL)

(21) Appl. No.: 16/405,981

(22) Filed: May 7, 2019

Related U.S. Application Data
(60) Provisional application No. 62/671,474, filed on May 15, 2018.

(51) Int. Cl. G06T 7/00; H01L 21/67

(52) U.S. Cl. CPC G06T 7/001; G06T 2207/30148; G06T 2207/10152; H01L 21/67288

(57) ABSTRACT

A method for detecting cross talk, that may include acquiring a first image of a region of interest (ROI) of a wafer by illuminating the ROI with a first oblique beam, and collecting light reflected from the ROI; acquiring a second image of the ROI by illuminating the ROI with a second oblique beam, and collecting light reflected from the ROI; wherein a orthogonal projection of the first oblique beam on the wafer is oriented to a orthogonal projection of the second oblique beam on the wafer; and detecting cross talk that appears in at least one of first image of the region and the second image of the region.

### REFERENCE

This application claims priority from U.S. provisional patent 62/671,474 filing date May 15, 2019 which is incorporated herein by reference.

### BACKGROUND OF THE INVENTION

Wafers may include multiple structural elements that may reflect light towards each other—thereby create cross talk.

Accordingly—when a first structural element is illuminated—the first structural element may reflect radiation towards (directly or indirectly) a second structural element. The second structural element may reflect at least some of the radiation towards a sensor that should have sensed only light reflected from the first structural element—so that the image of the first structural element will also include unwanted information about the second structural element.

There is a growing need to detect cross talk.

### SUMMARY

There may be provided a method for detecting cross talk, the method may include acquiring a first image of a region of interest (ROI) of a wafer by illuminating the ROI with a first oblique beam, and collecting light reflected from the ROI; acquiring a second image of the ROI by illuminating the ROI with a second oblique beam, and collecting light reflected from the ROI; wherein a orthogonal projection of the first oblique beam on the wafer may be oriented to a orthogonal projection of the second oblique beam on the wafer; and detecting cross talk that appears in at least one of first image of the region and the second image of the region.

The detecting of the cross talk may include searching for an image, out of the first image and the second image that may be substantially free of cross talk.

The method may include continuing to acquire additional images of the ROI until finding an image that may be substantially free of cross talk, wherein the additional images may be acquired by illuminating the region of interest of the wafer by oblique radiation beams that have orthogonal projections on the wafer that may be oriented to each other.

The detecting of the cross talk may be based on a comparison between the first image and the second image.

The comparing may include evaluating differences between spatial distributions of pixels of substantially the same value in the first image and in the second image.

The method may include introducing a rotational movement, about an axis that may be oriented to the wafer, between the wafer and an illumination unit that generates the first and second radiation beams; wherein the introducing of the rotational movement may be executed after the acquiring of the first image of the ROI and before acquiring the second image of the ROI.

The first oblique beam may be generated by a first illumination unit and the second oblique beam may be generated by a second illumination unit.

The detecting of the cross talk may be based on a reference model of the ROI.

The first image and the second image embed height information and wherein the detecting of the cross talk may be based on expected height values of elements of the ROI.

The illuminating of the ROI with the first oblique beam may include scanning the ROI with the first oblique beam.

The method wherein the first oblique beam forms a spot on the ROI.

The method wherein the first oblique beam forms a line on the ROI.

The acquiring of the first image may include utilizing a triangulation system.

The detecting of the cross talk may be followed by generating an estimate of the ROI.

The detecting of the cross talk may be followed by generating a three dimensional estimate of the ROI.

There may be provided a non-transitory computer readable medium that may store instructions for acquiring a first image of a region of interest (ROI) of a wafer by illuminating the ROI with a first oblique beam, and collecting light reflected from the ROI; acquiring a second image of the ROI by illuminating the ROI with a second oblique beam, and collecting light reflected from the ROI; wherein a orthogonal projection of the first oblique beam on the wafer may be oriented to an orthogonal projection of the second oblique beam on the wafer; and detecting cross talk that appears in at least one of first image of the region and the second image of the region.

The detecting of the cross talk may include searching for an image, out of the first image and the second image that may be substantially free of cross talk.

The non-transitory computer readable medium that may store instructions for continuing to acquire additional images of the ROI until finding an image that may be substantially free of cross talk, wherein the additional images may be acquired by illuminating the region of interest of the wafer by oblique radiation beams that have orthogonal projections on the wafer that may be oriented to each other.

The detecting of the cross talk may be based on a comparison between the first image and the second image.

The comparing may include evaluating differences between spatial distributions of pixels of substantially the same value in the first image and in the second image.

The non-transitory computer readable medium that may store instructions for introducing a rotational movement, about an axis that may be oriented to the wafer, between the wafer and an illumination unit that generates the first and second radiation beams; wherein the introducing of the rotational movement may be executed after the acquiring of the first image of the ROI and before acquiring the second image of the ROI.

The first oblique beam may be generated by a first illumination unit and the second oblique beam may be generated by a second illumination unit.

The detecting of the cross talk may be based on a reference model of the ROI.

The first image and the second image embed height information and wherein the detecting of the cross talk may be based on expected height values of elements of the ROI.

The illuminating of the ROI with the first oblique beam may include scanning the ROI with the first oblique beam.

The first oblique beam forms a spot on the ROI.

The first oblique beam forms a line on the ROI.

The acquiring of the first image may include utilizing a triangulation system.

The detecting of the cross talk may be followed by generating an estimate of the ROI.

The detecting of the cross talk may be followed by generating a three dimensional estimate of the ROI.

There may be provided an evaluation system that may include an imager, an optical unit, a chuck and a processor; wherein the chuck may be configured to support a wafer; wherein the optical unit may be configured to (a) acquire a first image of a region of interest (ROI) of a wafer by illuminating the ROI with a first oblique beam, and (b) collecting light reflected from the ROI; acquire a second image of the ROI by illuminating the ROI with a second oblique beam, and collecting light reflected from the ROI; wherein a orthogonal projection of the first oblique beam on the wafer may be oriented to an orthogonal projection of the second oblique beam on the wafer; and wherein the processor may be configured to detect cross talk that appears in at least one of first image of the region and the second image of the region.

The processor may be configured to detect of the cross talk by searching for an image, out of the first image and the second image that may be substantially free of cross talk.

The evaluation system may include continuing to acquire additional images of the ROI until finding an image that may be substantially free of cross talk, wherein the additional images may be acquired by illuminating the region of interest of the wafer by oblique radiation beams that have orthogonal projections on the wafer that may be oriented to each other.

The processor may be configured to detect of the cross talk. The cross talk detection may be based on a comparison between the first image and the second image.

The comparing may include evaluating differences between spatial distributions of pixels of substantially the same value in the first image and in the second image.

The chuck may be supported by a stage that may be configured to introducing a rotational movement, about an axis that may be oriented to the wafer, between the wafer and the optical unit; wherein the introducing of the rotational movement may be executed after the acquiring of the first image of the ROI and before acquiring the second image of the ROI.

The first oblique beam may be generated by a first illumination unit of the optical unit and the second oblique beam may be generated by a second illumination unit of the optical unit.

The processor may be configured to detect of the cross talk. The cross talk detection may be based on a reference model of the ROI.

The first image and the second image embed height information and wherein the processor may be configured to detect of the cross talk based on expected height values of elements of the ROI.

The optical unit may be configured to illuminate of the ROI with the first oblique beam by scanning the ROI with the first oblique beam.

The first oblique beam forms a spot on the ROI.

The first oblique beam forms a line on the ROI.

The evaluation system may be a triangulation system.

The processor may be configured to detect of the cross talk by generating an estimate of the ROI.

The processor may be configured to detect of the cross talk by generating a three dimensional estimate of the ROI.

### BRIEF DESCRIPTION OF THE INVENTION

The present invention will be understood and appreciated more fully from the following detailed description taken in conjunction with the drawings in which:

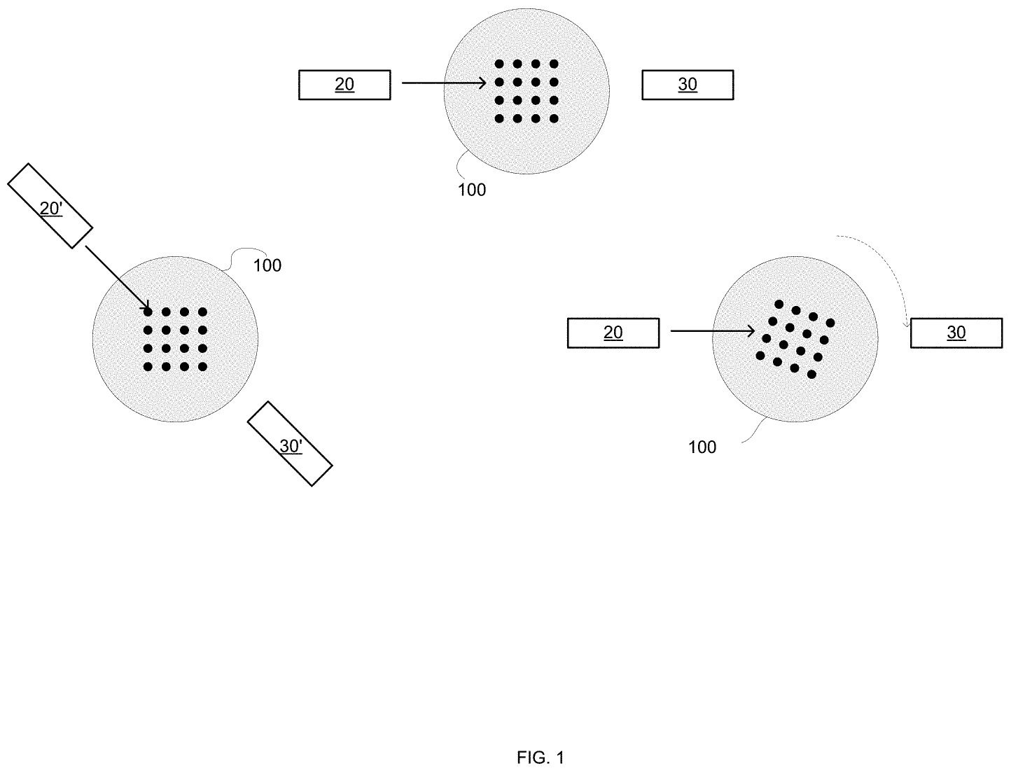

FIG. 1 illustrates a wafer and various spatial relationships between the wafer and components of an evaluation system;

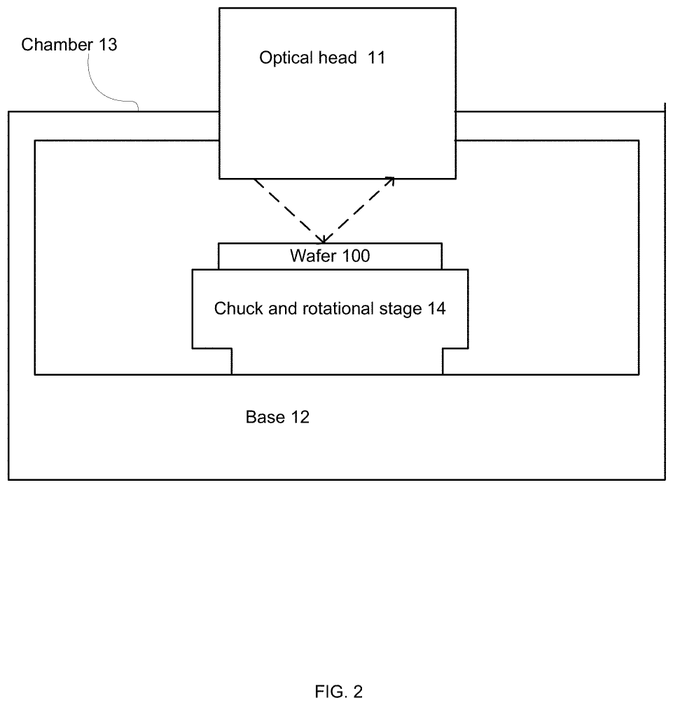

FIG. 2 illustrates an example of a wafer and an evaluation system;

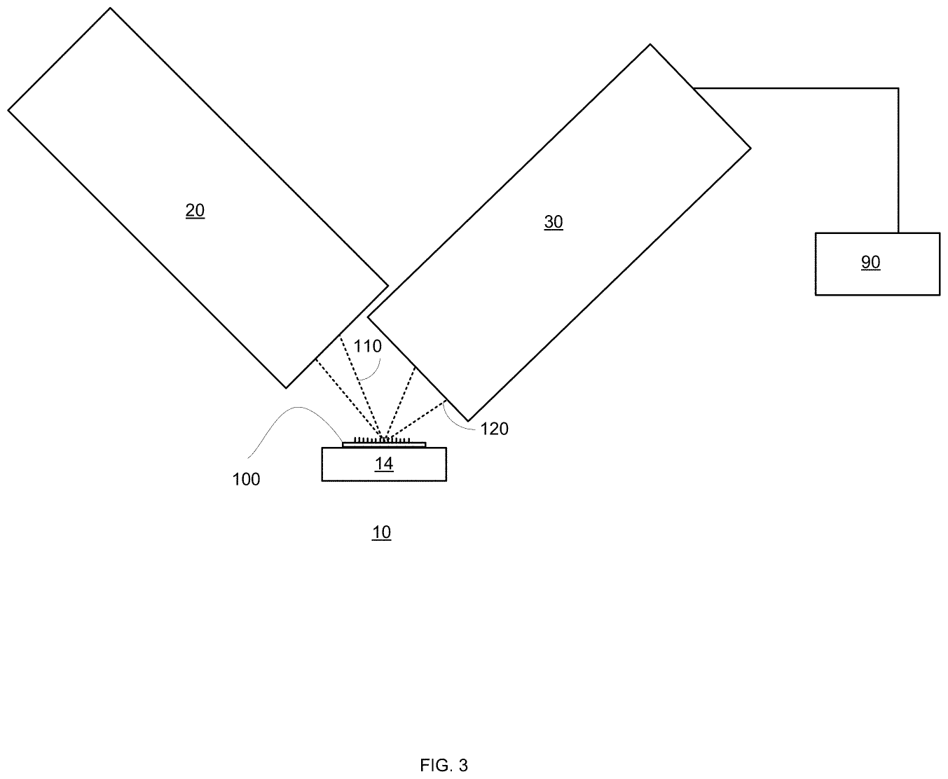

FIG. 3 illustrates an example of a wafer and an evaluation system;

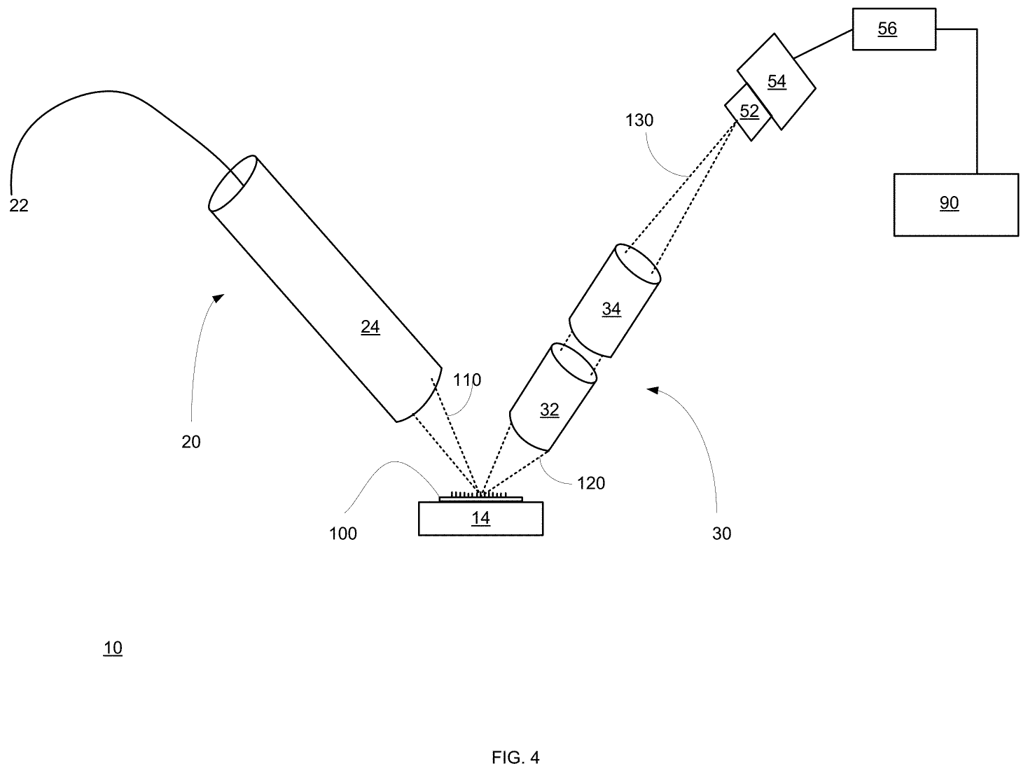

FIG. 4 illustrates an example of a wafer and an evaluation system;

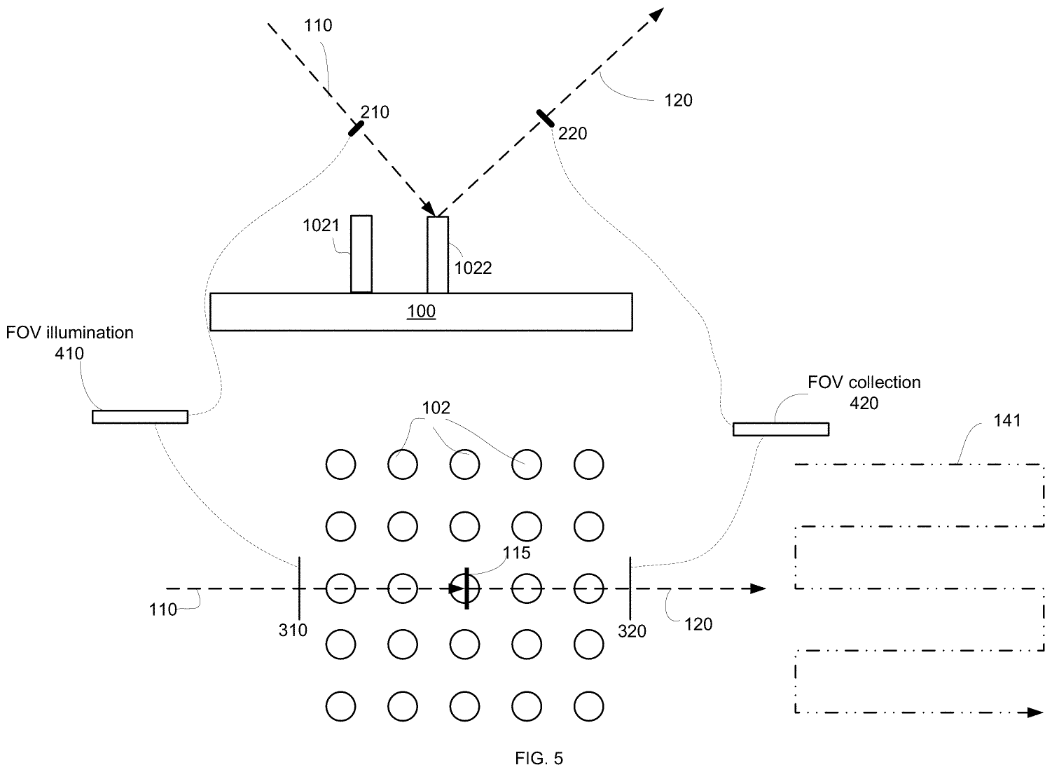

FIG. 5 illustrates an example of a region of interest (ROI) of a wafer, a scan pattern, and a cross talk free scenario;

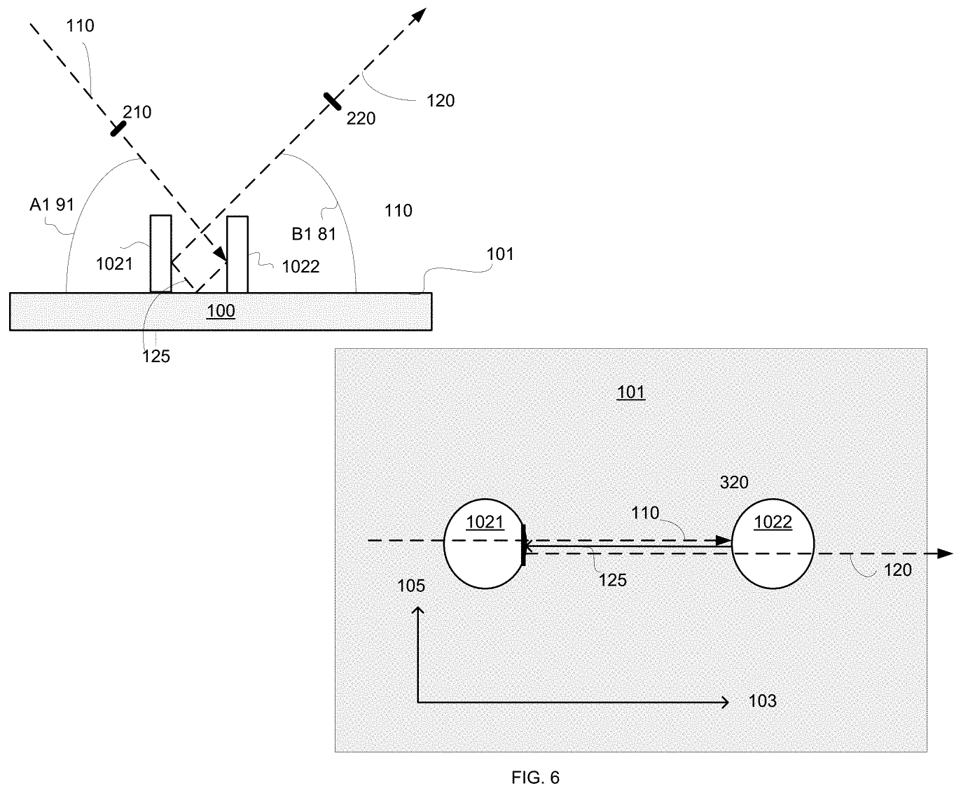

FIG. 6 illustrates an example of a cross talk scenario;

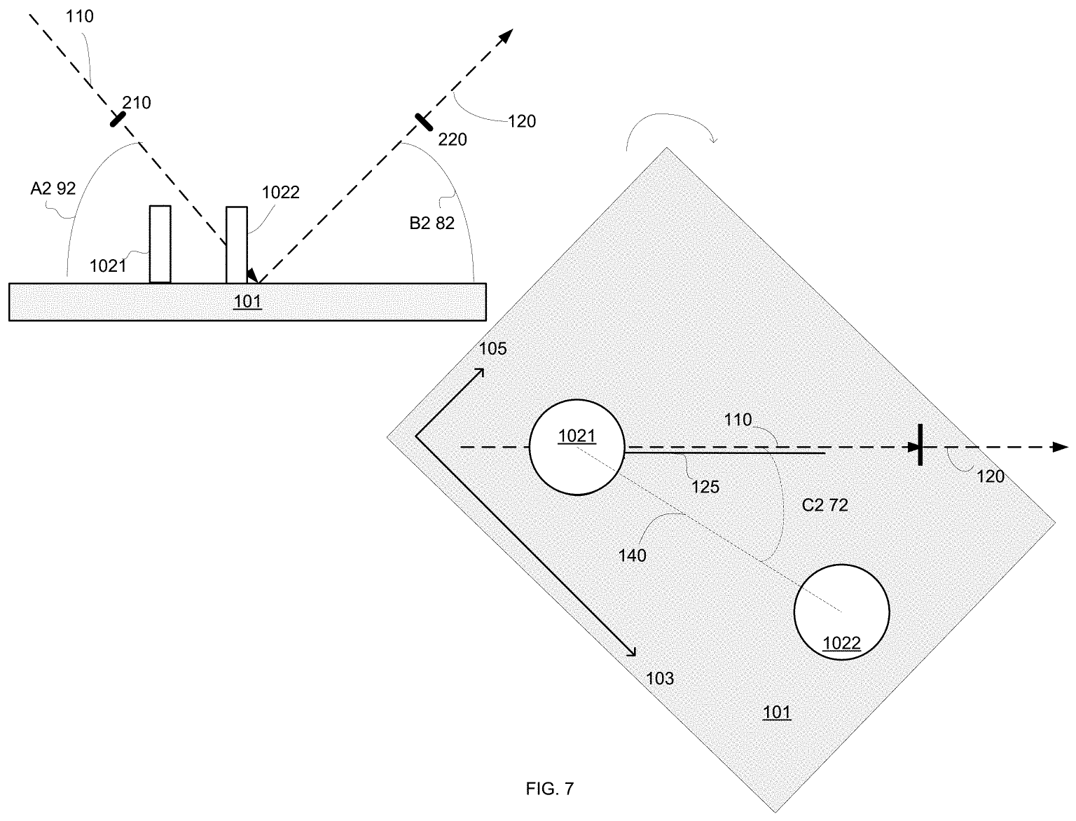

FIG. 7 illustrates an example of a cross talk free scenario;

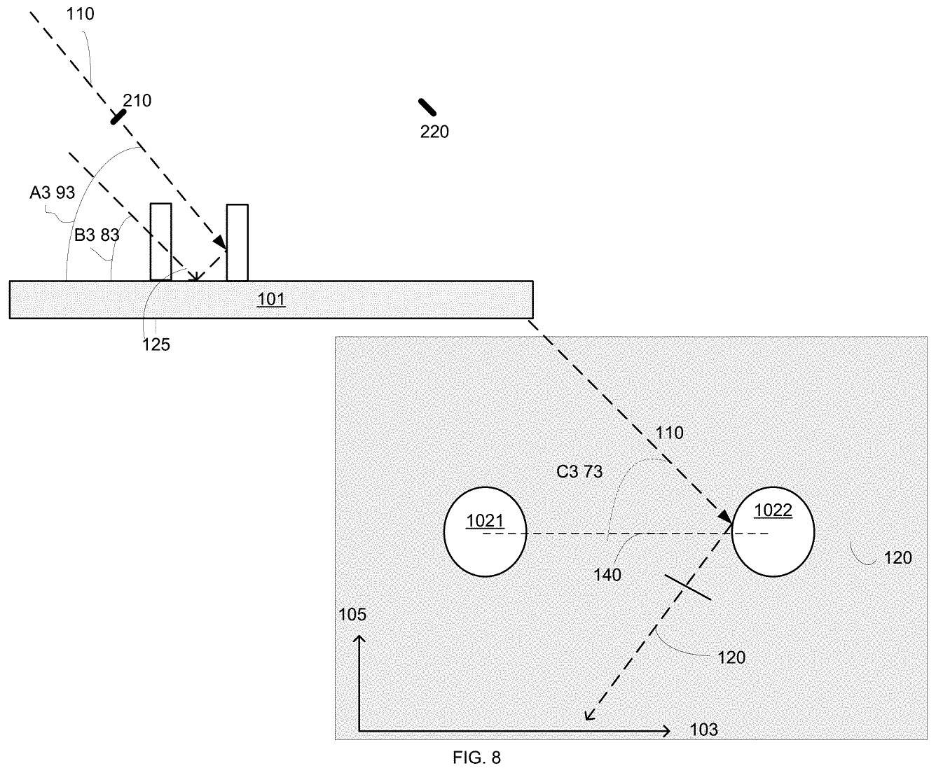

FIG. 8 illustrates an example of a cross talk free scenario;

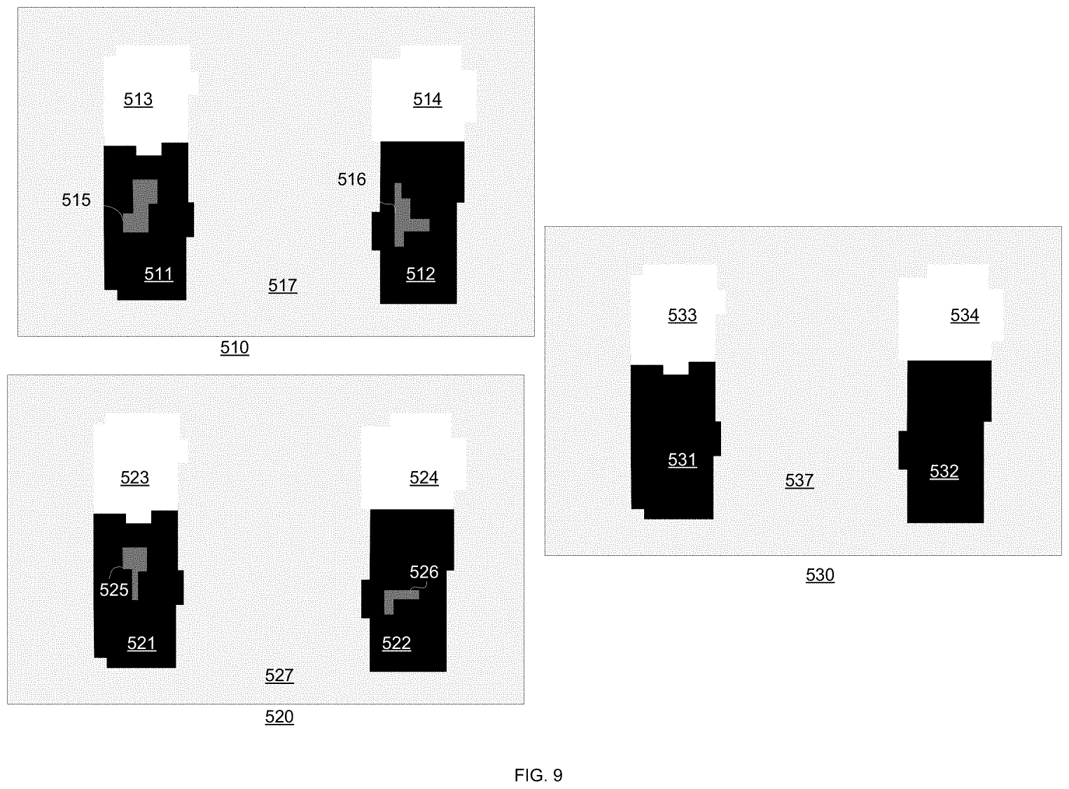

FIG. 9 illustrates an example images of two structural features;

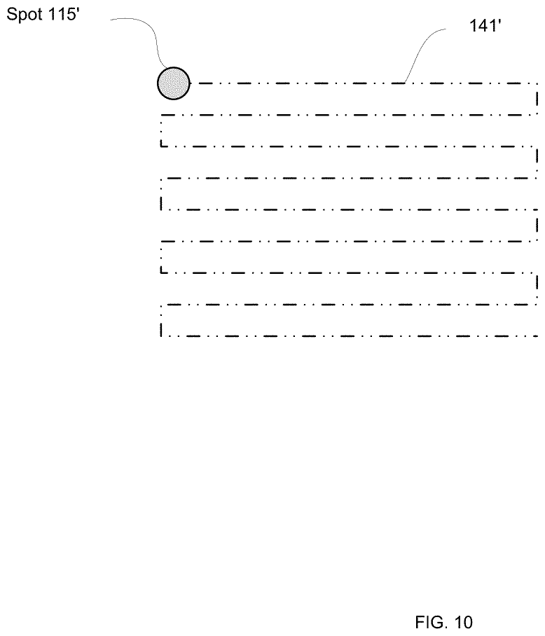

FIG. 10 illustrates an example of a scan pattern; and

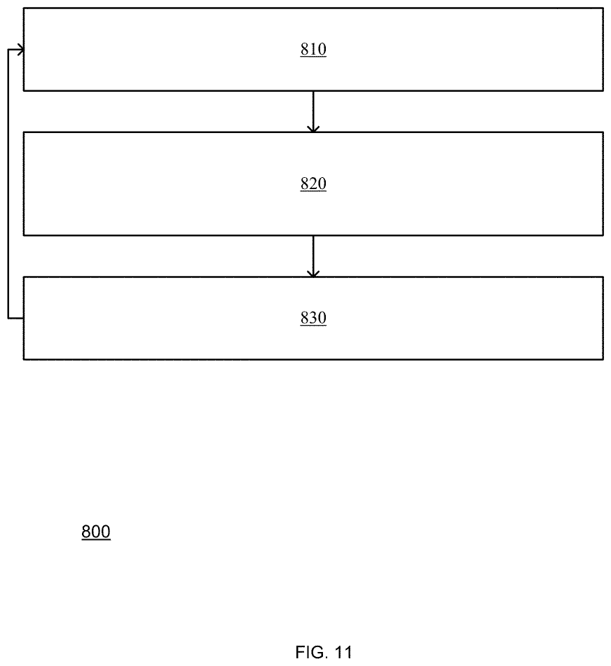

FIG. 11 illustrates examples of a method.

### DETAILED DESCRIPTION OF THE INVENTION

Because the apparatus implementing the present invention is, for the most part, composed of optical components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

In the following specification, the invention will be described with reference to specific examples of embodiments of the invention. It will, however, be evident that various modifications and changes may be made therein without departing from the broader spirit and scope of the invention as set forth in the appended claims.

The word “comprising” does not exclude the presence of other elements or steps then those listed in a claim. It is understood that the terms so used are interchangeable under appropriate circumstances such that the embodiments of the invention described herein are, for example, capable of operation in other orientations than those illustrated or otherwise described herein.

There may be provided a method and a system for detecting and/or reducing cross talk.

The system may be an evaluation system such as an inspection unit, a metrology system, a triangulation unit, a 3D imaging unit, and the like.

For brevity of explanation it is assumed that the system is a triangulation system.

The following text refers to a wafer but a wafer is merely a non-limiting example of an object such as but not limited to a panel, a printed circuit board (PCB), and the like.

The method may include multiple repetitions of:
a. Acquiring an image of a region of interest (ROI) of a wafer by illuminating (using an illumination module) the ROI of the wafer from a certain direction and collecting light reflected from the ROI of the wafer,
b. Introducing a rotational movement between the wafer and illumination module thereby changing the angular relationship between the illumination module and the ROI of the wafer—and jumping to step (a).

The ROI may be of any shape and/or size.

The ROI may be located within a single field of view (FOV) of the evaluation system, may expand outside a single FOV of the evaluation system. The entire wafer (or only part of the wafer) may be imaged, one FOV after the other.

Multiple repetitions of steps (a) and (b) provide multiple images of the ROI of the wafer. These multiple images are acquired at different angular relationships—some of the angular relationships may provide images with reduced cross talk or even without cross talk.

These images may be processed (step (c)) to find cross talk free images. It is noted that when the ROI includes multiple structural elements—different images (acquired during different iterations of steps (a) and (b) may include cross talk free information of different structural elements.

Step (c) may include comparing between the images may assist in finding cross talk information in an image and may be followed by eliminating the cross talk information from any one of the images.

Step (c) may be followed by step (d) of using the cross talk free information to estimate or evaluate any properties and/or parameters and/or features of the ROI—for example the shape and/or size and/or dimensions and/or spatial relationships between structural elements within the ROI.

The amount of the rotational movement may be determined in advance, may be learnt by acquiring different images, may be estimated based on at least one out of the shape, size, reflectivity and the spatial relationships between the structural element, and the like.

It should be noted that the rotation angle (x) of the substrate under the inspection shall be chosen out of the following range: 180 degrees<x<90 or 90 degrees<x<0 degrees. In a way that the chosen angle of rotation may (or may not) fall into a strict angles of 180, 90, 0 degrees.

It should be notes that any rotation angle may be used within 0-360 degrees.

The upper, lower and right parts of FIG. 1 illustrates a wafer 100 and an triangulation system 10 that includes an illumination unit 20 and a collection unit 30. The left part of FIG. 1 illustrates an additional illumination unit 20′ and an additional collection unit 30′. The bottom part of FIG. 1 illustrates that the illumination unit 20 and a collection unit 30 were rotated in relation to wafer 100. The right part illustrates that wafer 100 was rotated in relation to the triangulation system.

FIG. 2 illustrates an example of a triangulation system 10 and a wafer 100.

The triangulation system 10 includes
a. an optical head 11 that may illuminate the ROI with oblique beam 110, 110 and 120 are not depicted in FIG. 2 and sense reflected beam 120 that is reflected from the ROI,
b. a chamber 13 (or other structural element or frame) that has a base 12,
c. a chuck and mechanical stage 14 that supports and moves wafer 100.

It is noted that the optical head 11 may be rotated by a rotating stage—or that both optical head and chuck may be rotated. The wafer is evaluated while positioned in the chamber 13. The chamber may or may not be sealed.

FIG. 3 illustrates an example of a triangulation system 10 and wafer 100.

Triangulation system 10 includes illumination unit 20, collection unit 30, chuck and mechanical stage 14, frame grabber 56, and processor 90.

The chuck is configured to support the wafer 100 while the mechanical stage may rotate the chuck and/or perform any other movement of the chuck.

The illumination unit 20 has an optical axis that is oblique to wafer 100 and it illuminates an ROI of wafer 100 with an oblique beam. The collection unit 30 is configured to collect light reflected from the ROI.

The illumination unit and the collection unit may belong to an optical head.

The triangulation system 10 may collect different images by illuminating the ROI of the wafer by oblique that differ from each other by their trajectory on wafer 100. Especially—orthogonal projections of different oblique beams may be non-parallel to each other.

The processor 90 may process an image generated by the collection unit 30.

The processor 90 may be configured to detect cross talk that appears in at least one of first image of the region and the second image of the region. The detection of the cross talk may be followed by calculating one or more properties and/or parameters and/or features of structural elements of the ROI— while substantially ignoring the detected cross talk.

FIG. 4 illustrates an example of a triangulation system 10.

Triangulation system 10 includes illumination unit 20, collection unit 30, first camera 54 (that is preceded by first camera optics 52), chuck and mechanical stage 14, frame grabber 56, and processor 90.

Illumination unit 20 is configured to illuminate the wafer 100 with an oblique beam 110 to form on a ROI of wafer 100 a light strip (denoted 115 in FIG. 5) that may be spatially incoherent. The ROI of wafer 100 includes a surface 101 and multiple structural elements such as but not limited to microscopic bumps.

Collection unit 30 is configured to collect light that is reflected from the object and to distribute the light to first camera 54.

The first camera 54 is configured to generate, during a height measurement process, detection signals indicative of heights of the multiple structural elements.

The mechanical stage is configured to introduce a movement, during the height measurement process, between the surface and each one of the illumination unit 20 and the collection unit 30.

Frame grabber 56 is configured to obtain the detection signals from the cameras and generate images of the ROI.

Processor 90 is configured to process the images to determine the heights of the multiple structural elements. The processing may include applying any known triangulation process. For example—the processor may apply the triangulation process illustrated in U.S. Pat. No. 8,363,229 of Ben-Levi. Processor 90 may include one or more general purpose unit chips or cores, one or more image processor chips or cores, one or more FPGAs, one or more computers, and the like.

FIG. 4 illustrates the illumination unit 20 as including a fiber 22 for feeding light to a Scheimpflug principle illumination unit 24. Triangulation system 10 may include other illumination units. Triangulation system 10 may include one or multiple illumination units although using a single illumination unit reduced the cost of the triangulation system and prevents the creation of interference patterns, cross talks and prevents using compensations processes for compensating between differences between light generated by different illumination units.

FIG. 4 also illustrates the collection unit 30 as including an objective lens 32 that is followed by a tube lens 34 that is followed by first camera optics 52. Triangulation system 10′ may include other collection units.

FIG. 5 includes a top view and a side view of the wafer 100, the oblique beam 110 (illuminated beam), the light strip 115 formed on the wafer, and the collected beam 120 according to an embodiment of the invention.

FIG. 5 illustrates that the collection unit 30 has a collection field of view (FOV collection) 420 that is elongated, has a length (320) that is parallel to the longitudinal axis of the light strip 115 and a width (220) that is perpendicular to the longitudinal axis of the light strip 115. Accordingly—the collection unit 30 collects light reflected within a narrow angular range.

FIG. 5 illustrates that the illumination unit 20 has an illumination field of view (FOV illumination) 410 that is elongated, has a length (310) that is parallel to the longitudinal axis of the light strip 115 and a width (210) that is perpendicular to the longitudinal axis of the light strip 115. Accordingly—the illumination unit 20 illuminates the object over a narrow angular range.

FIG. 5 also illustrates an example of a scan pattern 141. Other scan patterns may be provided.

In FIG. 5 the strip of light falls on (and is reflected from) the top of second structural element 1022. No cross talk is expected.

FIG. 6 illustrates an example of a cross talk scenario.

Oblique beam 110 impinges on second structural element 1022, is reflected (125) towards the surface 101 of the wafer, is reflected towards the first structural element 1021 and is finally reflected from the first structural element 1021 towards the collection unit.

The result of the cross talk is a reflected light beam that has an optical path that represent a false height reading.

FIG. 6 also illustrates that the orthogonal projection of the oblique beam 110 is parallel to an imaginary axis (not shown) between the centers of first and second structural elements 1021 and 1022 and is parallel to an imaginary longitudinal axis 103 and normal to a transverse axis 105.

FIG. 6 also illustrates that the angle between the surface of the wafer and oblique beam 110 is a first impingement angle A1 91, and that the reflection angle between the reflected beam 120 and the surface of the wafer is a first reflection angle B1 81.

FIG. 7 illustrates an example of lack of a cross talk.

Oblique beam 110 impinges on second structural element 1022 is reflected (125) towards the surface 101 of the wafer and then towards the collection unit. The reflected beam 120 is detected by the collection unit and reflects the height of the surface 101. Due to the rotation of the wafer, the second structural element is not in the path of the oblique beam.

FIG. 7 also illustrates that the orthogonal projection of the first oblique beam 110 is oriented (by angle C2 72) to an imaginary axis 140 between the centers of 1021 and 1022 and is oriented to an imaginary longitudinal axis 103 and normal to a transverse axis 105.

FIG. 7 also illustrates that the angle between the surface of the wafer and oblique beam 110 is a second impingement angle A2 92, and that the reflection angle between the reflected beam 120 and the surface of the wafer is a second reflection angle B2 82.

The first and second impingement angles may be the same or may differ from each other. The first and second reflection angles may be the same or may differ from each other.

FIG. 8 illustrates an example of lack of signal.

In relation to FIG. 7—the optical head was rotated.

Oblique beam 110 impinges on second structural element 1022, and is reflected (125) towards the surface 101 of the wafer and then away from the collection unit—so that no signal is detected by the collection unit.

FIG. 8 also illustrates that the orthogonal projection of the oblique beam 110 is oriented (by angle C3 73) to an imaginary axis 140 between the centers of 1021 and 1022 and is oriented to an imaginary longitudinal axis 103 and normal to a transverse axis 105.

FIG. 8 also illustrates that the angle between the surface of the wafer and oblique beam 110 is a third impingement angle A3 92 and that the reflection angle between the reflected beam 120 and the surface of the wafer is a third reflection angle B3 83.

Any relationship may exist between the first, second and third impingement angles. The third reflection angle differs from the first and second reflection angles.

FIG. 9 is an example of first, second, and third images 510, 520 and 530 of of first and second structural elements. The images are taken at different angles.

In all three images the top of the first structural element is represented by bright pixelated regions 513, 523 and 533 that represent a height that is within the range of expected top structural element height range. See, for example, FIG. 5.

In all three images the top of the second structural element is represented by bright pixelated regions 514, 524 and 534 that represent a height that is within the range of expected top structural element height range. See, for example, FIG. 5.

In all three images the surface of the wafer is represented by light gray pixelated regions 517, 527 and 537 that represent a height that is within the range of expected surface height range. See, for example, FIG. 7.

In all three images a majority of the sidewall of the first structural element is represented by dark pixelated regions 511, 521 and 531 that represent a lack of signal. See, for example, FIG. 8.

In all three images a majority of the sidewall of the second structural element is represented by dark pixelated regions 512, 522 and 532 that represent a lack of signal. See, for example, FIG. 8.

In the first and second images the cross talk signals are represented by gray pixelated regions 515, 525, 516 and 526 that are surrounded by dark pixelated regions 511, 521, 512 and 522 respectively. These regions represent height readings that are outside an expected height range of the top of the structural elements and of the surface of the wafer.

It is further noted that difference, between the first, second and third images, in the shape and/or size (spatial distribution) of the pixelated gray regions 515, 525, 516 and 526 exceed the difference between other regions.

FIG. 10 illustrates a scanning pattern 141′ of a ROI that is applied when the oblique beam form a spot 115′ on the ROI. It should be noted that any scanning pattern may be used and that the oblique beam may have any cross section when impinging on the ROI.

FIG. 11 illustrates an example of a method 800.

Method 800 may include acquiring multiple images of an ROI of a wafer. The multiple images may be acquired by illuminating the ROI by oblique beams that have orthogonal projection s on the wafer that may be oriented to each other. For example—the following description discusses a first image and a second image and optionally one or more additional images.

Method 800 may include:
a. Step 810 of acquiring a first image of a region of interest (ROI) of a wafer by illuminating the ROI with a first oblique beam, and collecting light reflected from the ROI.
b. Step 820 of acquiring a second image of the ROI by illuminating the ROI with a second oblique beam, and collecting light reflected from the ROI. A orthogonal projection of the first oblique beam on the wafer may be oriented to a orthogonal projection of the second oblique beam on the wafer.
c. Step 830 of detecting cross talk that appears in at least one of first image of the region and the second image of the region.

Step 830 may include searching for an image, out of the first image and the second image may be substantially free of cross talk. Once such an image is found the method may evaluate one or more features and/or parameters of the ROI.

Method 800 may include continuing to acquire additional images of the ROI until finding an image that may be substantially free of cross talk, wherein the additional images may be acquired by illuminating the region of interest of the wafer by oblique radiation beams that have orthogonal projections on the wafer that may be oriented to each other. Other stop conditions may be applied—for example the number of repetitions may be set in advance. The repetitions may be conditioned by reaching a number of repetitions and/or finding a cross talk image that is substantially free of cross talk.

Step 830 may be based on a comparison between the first image and the second image. For example—searching for region that most changes between one image to the other, regions that appear in only one of the images, and the like.

The comparing may include evaluating differences between spatial distributions of pixels of substantially a same value in the first image and in the second image. See, for example, FIG. 9.

The method may include step 820 of introducing a rotational movement, about an axis that may be oriented to the wafer, between the wafer and an illumination unit that generates the first and second radiation beams. Step 820 may follow step 810 and precede step 830.

The first oblique beam (of step 810) may be generated by a first illumination unit and the second oblique beam (of step 820) may be generated by a second illumination unit.

The detecting of the cross talk may be based on a reference model of the ROI. For example—searching for measurements that do not reflect the model. For example—the first image and the second image may embed height information and wherein the detecting of the cross talk may be based on expected height values of elements of the ROI.

The illuminating of the ROI with the first oblique beam may include scanning the ROI with the first oblique beam.

Method 800 may be executed by a triangulation system or any other 3D imaging system.

The detecting of the cross talk may be followed by generating an estimate of the ROI. Accordingly—one the cross talk is detected then any parameter of features of the ROI may be found.

The detecting of the cross talk may be followed by generating a three dimensional estimate of the ROI.

There may be provided a method that may include creating a 3D reference at a certain angle (for example angle of zero degrees)—this may include acquiring an image from the certain angle (that image may include cross talk), detecting the cross talk in the certain image (for example by executing iterations of steps 810 and 820) and remove the cross talk from the certain image to provide a cross talk free reference image. Thus—the removal of the cross talk may include identify the real reflections, then incorporate that information to the reference image.

This may allow to scan (during inspection) at a certain angle (for example zero angle) using the reference image (after cleared from cross talk) to detect defects.

Thus—the method may include:
1. Scan at an certain (for example zero) angle for reference creation with the cross talk. The angle is a radial angle in relation to the center of the object.
2. Scan a different angle to single the real top reflections.
3. Rotate the angled image to align with the reference image. For example—all the reflections that remain static are real. The rest are noise.
4. Scan for clean the wafer at the certain angle.

The terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe.

Thus, these terms are not necessarily intended to indicate temporal or other prioritization of such elements. The mere fact that certain measures are recited in mutually different claims does not indicate that a combination of these measures cannot be used to advantage.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

The phrase “may be X” indicates that condition X may be fulfilled. This phrase also suggests that condition X may not be fulfilled. For example—any reference to a system as including a certain component should also cover the scenario in which the system does not include the certain component. For example—any reference to a method as including a certain step should also cover the scenario in which the method does not include the certain component. Yet for another example—any reference to a system that is configured to perform a certain operation should also cover the scenario in which the system is not configured to perform the certain operation.

The terms “including”, “comprising”, “having”, “consisting” and “consisting essentially of” are used in an interchangeable manner. For example—any method may include at least the steps included in the figures and/or in the specification, only the steps included in the figures and/or the specification.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

Also for example, the examples, or portions thereof, may implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems’.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one as or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements the mere fact that certain measures are recited in mutually different claims does not indicate that a combination of these measures cannot be used to advantage.

Any system, apparatus or device referred to this patent application includes at least one hardware component.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A method for detecting cross talk, the method comprises:
acquiring a first image of a region of interest (ROI) of a wafer by illuminating the ROI with a first oblique beam, and collecting light reflected from the ROI;
acquiring a second image of the ROI by illuminating the ROI with a second oblique beam, and collecting light reflected from the ROI;
wherein a orthogonal projection of the first oblique beam on the wafer is oriented to a orthogonal projection of the second oblique beam on the wafer; and
detecting cross talk that appears in at least one of first image of the region and the second image of the region.

2. The method according to claim 1 wherein the detecting of the cross talk comprises searching for an image, out of the first image and the second image that is substantially free of cross talk.

3. The method according to claim 1 comprising continuing to acquire additional images of the ROI until finding an image that is substantially free of cross talk, wherein the additional images are acquired by illuminating the region of interest of the wafer by oblique radiation beams that have orthogonal projections on the wafer that are oriented to each other.

4. The method according to claim 1 wherein the detecting of the cross talk is based on a comparison between the first image and the second image.

5. The method according to claim 4 wherein the comparing comprises evaluating differences between spatial distributions of pixels of substantially a same value in the first image and in the second image.

6. The method according to claim 1 comprising introducing a rotational movement, about an axis that is oriented to the wafer, between the wafer and an illumination unit that generates the first and second radiation beams; wherein the introducing of the rotational movement is executed after the acquiring of the first image of the ROI and before acquiring the second image of the ROI.

7. The method according to claim 1 wherein the first oblique beam is generated by a first illumination unit and the second oblique beam is generated by a second illumination unit.

8. The method according to claim 1 wherein the detecting of the cross talk is based on a reference model of the ROI.

9. The method according to claim 1 wherein the first image and the second image embed height information and wherein the detecting of the cross talk is based on expected height values of elements of the ROI.

10. The method according to claim 1 wherein the illuminating of the ROI with the first oblique beam comprises scanning the ROI with the first oblique beam.

11. The method according to claim 10 wherein the first oblique beam forms a spot on the ROI.

12. The method according to claim 10 wherein the first oblique beam forms a line on the ROI.

13. The method according to claim 1 wherein the acquiring of the first image comprising utilizing a triangulation system.

14. The method according to claim 1 wherein the detecting of the cross talk is followed by generating an estimate of the ROI.

15. The method according to claim 1 wherein the detecting of the cross talk is followed by generating a three dimensional estimate of the ROI.

16. A non-transitory computer readable medium that stores instructions for:
acquiring a first image of a region of interest (ROI) of a wafer by illuminating the ROI with a first oblique beam, and collecting light reflected from the ROI;
acquiring a second image of the ROI by illuminating the ROI with a second oblique beam, and collecting light reflected from the ROI;
wherein a orthogonal projection of the first oblique beam on the wafer is oriented to a orthogonal projection of the second oblique beam on the wafer; and
detecting cross talk that appears in at least one of first image of the region and the second image of the region.

17. The non-transitory computer readable medium according to claim 16 wherein the detecting of the cross talk comprises searching for an image, out of the first image and the second image is substantially free of cross talk.

18. The non-transitory computer readable medium according to claim 16 that stores instructions for continuing to acquire additional images of the ROI until finding an image that is substantially free of cross talk, wherein the additional images are acquired by illuminating the region of interest of the wafer by oblique radiation beams that have orthogonal projection s on the wafer that are oriented to each other.

19. The non-transitory computer readable medium according to claim 16 wherein the detecting of the cross talk is based on a comparison between the first image and the second image.

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. An evaluation system that comprises an imager, an optical unit, a chuck and a processor; wherein the chuck is configured to support a wafer;
wherein the optical unit is configured to:
acquire a first image of a region of interest (ROI) of a wafer by illuminating the ROI with a first oblique beam, and collecting light reflected from the ROI;
acquire a second image of the ROI by illuminating the ROI with a second oblique beam, and collecting light reflected from the ROI;
wherein a orthogonal projection of the first oblique beam on the wafer is oriented to a orthogonal projection of the second oblique beam on the wafer; and
wherein the processor is configured to detect cross talk that appears in at least one of first image of the region and the second image of the region.

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)
